(19) United States
(12) Patent Application Publication
(10) Pub. No.: US 2025/0167749 A1
(43) Pub. Date: May 22, 2025

(54) ELECTRONIC COMPONENT

(71) Applicant: Murata Manufacturing Co., Ltd., Nagaokakyo-shi (JP)

(72) Inventor: Yosuke MATSUSHITA, Nagaokakyo-shi (JP)

(21) Appl. No.: 19/032,099

(22) Filed: Jan. 19, 2025

Related U.S. Application Data
(63) Continuation of application No. PCT/JP2023/019512, filed on May 25, 2023.

(30) Foreign Application Priority Data
Jul. 19, 2022 (JP) 2022-114772

(51) Int. Cl. H03H 7/01; H01G 4/30; H03H 1/00

(52) U.S. Cl. CPC H03H 7/0115; H01G 4/30; H03H 2001/0085

(57) ABSTRACT

A mounting electrode is provided on a mounting surface and not provided on a side surface, an upper surface, a first curved surface, or a second curved surface. A region with the first curved surface in the up-down direction is defined as a first region. A region with the second curved surface in the up-down direction is defined as a second region. A distance in an orthogonal direction orthogonal to the up-down direction between a plurality of conductor layers located in the first region among the plurality of conductor layers and the side surface increases toward the mounting surface, and/or a distance in the orthogonal direction between a plurality of conductor layers located in the second region among the plurality of conductor layers and the side surface increases toward the upper surface.

### CROSS REFERENCE TO RELATED APPLICATION

This is a continuation of International Application No. PCT/JP2023/019512 filed on May 25, 2023 which claims priority from Japanese Patent Application No. 2022-114772 filed on Jul. 19, 2022. The contents of these applications are incorporated herein by reference in their entireties.

### BACKGROUND OF THE DISCLOSURE

### Field of the Disclosure

The present disclosure relates to an electronic component.

### Description of the Related Art

As an invention related to the conventional electronic component, for example, a laminated filter disclosed in Patent Literature 1 is known. This laminated filter includes a main body and a plurality of electrodes. The main body has a structure in which a plurality of dielectric layers are stacked. The plurality of electrodes are provided in the main body. The plurality of electrodes provide an LC filter.
(Patent Literature 1) International Publication No. 2017/199734

### BRIEF SUMMARY OF THE DISCLOSURE

Incidentally, when the laminated filter disclosed in Patent Literature 1 is mounted on a circuit board, stray capacitance may be generated between the plurality of electrodes and an electrode on the circuit board. Such stray capacitance may become a cause to vary the characteristics of the LC filter from a desired value.

In view of the foregoing, exemplary embodiments of the present disclosure are directed to provide an electronic component capable of reducing stray capacitance to be generated between a conductor layer in a stacked body and a conductor layer of a circuit board.

An electronic component according to one exemplary embodiment of the present disclosure includes a stacked body including a structure in which a plurality of insulator layers are stacked in an up-down direction, a mounting surface oriented in a down direction, an upper surface oriented in an up direction, a side surface located between the mounting surface and the upper surface, a first curved surface located between the mounting surface and the side surface, and a second curved surface located between the upper surface and the side surface, a plurality of conductor layers provided in the stacked body, and a mounting electrode provided on the mounting surface and not provided on the side surface, the upper surface, the first curved surface, or the second curved surface, and a region with the first curved surface in the up-down direction is defined as a first region, a region with the second curved surface in the up-down direction is defined as a second region, a region without the first curved surface or the second curved surface in the up-down direction is defined as a third region, and at least one of a distance in an orthogonal direction orthogonal to the up-down direction between one or more conductor layers located in the first region among the plurality of conductor layers and the side surface, or a distance in the orthogonal direction orthogonal to the up-down direction between a plurality of conductor layers located in the second region among the plurality of conductor layers and the side surface is longer than a shortest distance in the orthogonal direction orthogonal to the up-down direction between a plurality of conductor layers located in the third region among the plurality of conductor layers and the side surface.

An electronic component according to one exemplary embodiment of the present disclosure includes a stacked body including a structure in which a plurality of insulator layers are stacked in an up-down direction, a mounting surface oriented in a down direction, an upper surface oriented in an up direction, a side surface located between the mounting surface and the upper surface, a first curved surface located between the mounting surface and the side surface, and a second curved surface located between the upper surface and the side surface, a plurality of conductor layers provided in the stacked body, and a mounting electrode provided on the mounting surface and not provided on the side surface, the upper surface, the first curved surface, or the second curved surface, and a region with the first curved surface in the up-down direction is defined as a first region, a region with the second curved surface in the up-down direction is defined as a second region, and a distance in an orthogonal direction orthogonal to the up-down direction between a plurality of conductor layers located in the first region among the plurality of conductor layers and the side surface increases toward the mounting surface, and/or a distance in the orthogonal direction between a plurality of conductor layers located in the second region among the plurality of conductor layers and the side surface increases toward the upper surface.

According to the electronic component in the present disclosure, stray capacitance to be generated between a conductor layer in a stacked body and a conductor layer of a circuit board is able to be reduced.

### BRIEF DESCRIPTION OF THE SEVERAL VIEWS OF THE DRAWINGS

FIG. 1 is an external perspective view of an electronic component 10.

FIG. 2 is a cross-sectional view near a mounting surface of the electronic component 10.

FIG. 3 is a cross-sectional view near an upper surface of the electronic component 10.

FIG. 4 is a cross-sectional view of an electronic component 1010 according to a comparative example.

FIG. 5 is an exploded perspective view of an electronic component 10a.

FIG. 6 is a cross-sectional view taken along a line A-A of the electronic component 10a.

FIG. 7 is a cross-sectional view taken along a line B-B of the electronic component 10a.

FIG. 8 is an exploded perspective view of an electronic component 10b.

FIG. 9 is a cross-sectional view taken along a line C-C of the electronic component 10b.

FIG. 10 is a cross-sectional view taken along a line C-C of an electronic component 10c.

### DETAILED DESCRIPTION OF THE DISCLOSURE

### Exemplary Embodiment

### (Structure of Electronic Component 10)

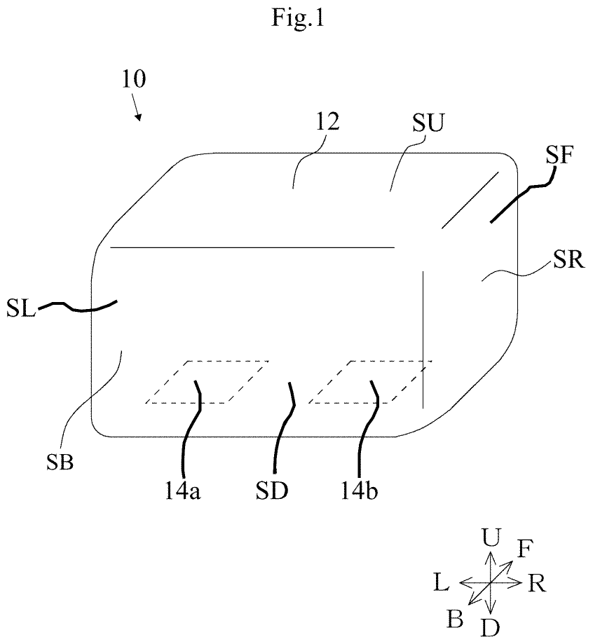

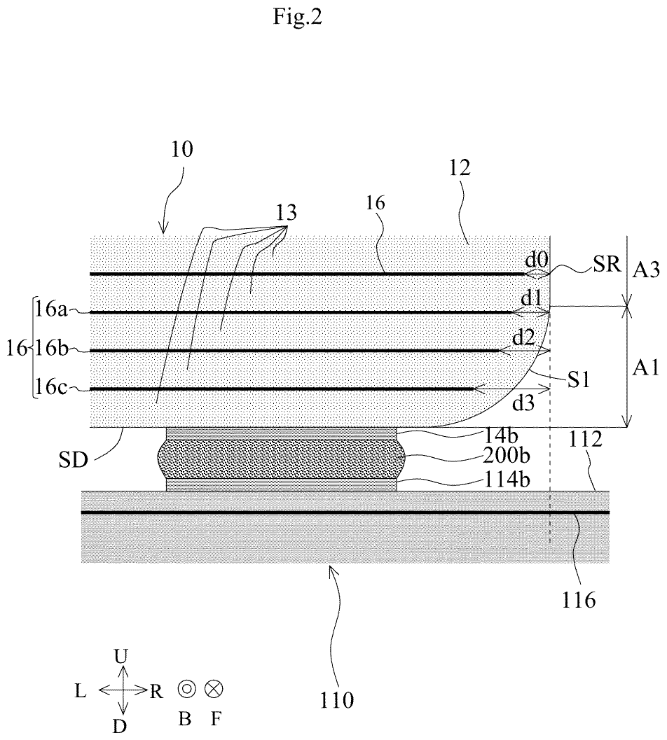

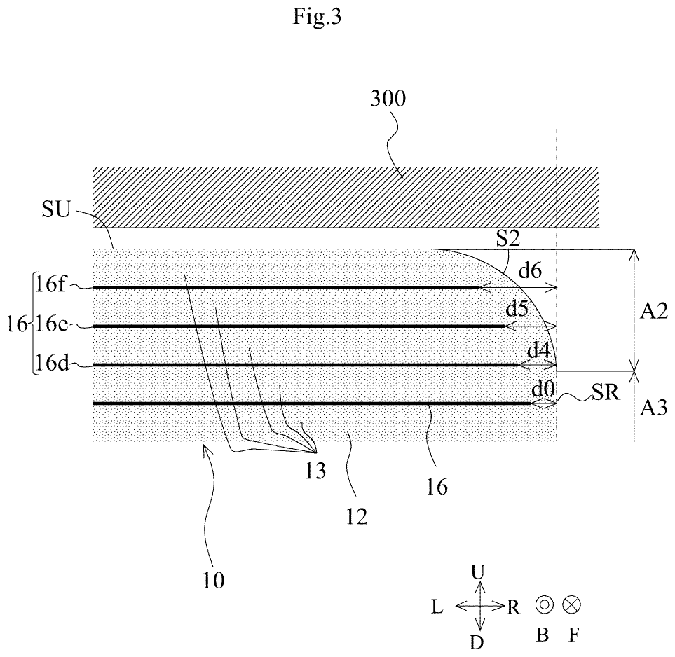

Hereinafter, a structure of an electronic component 10 according to exemplary embodiments of the present disclosure will be described with reference to drawings. FIG. 1 is an external perspective view of the electronic component 10. FIG. 2 is a cross-sectional view near a mounting surface of the electronic component 10. FIG. 3 is a cross-sectional view near an upper surface of the electronic component 10.

In the present specification, directions are defined as follows. A direction in which a plurality of insulator layers are stacked is defined as an up-down direction. The directions orthogonal to the up-down direction are defined as a left-right direction and a front-back direction. The left-right direction and the front-back direction are orthogonal to each other. It is to be noted that the up-down direction, the front-back direction, and the left-right direction in the present exemplary embodiment may not match the up-down direction, the front-back direction, and the left-right direction during the use of the electronic component 10.

First, the structure of the electronic component 10 will be described with reference to FIG. 1 and FIG. 2. The electronic component 10 is, for example, used for a wireless-communication terminal such as a smartphone. The electronic component 10, as shown in FIG. 1, includes a stacked body 12, mounting electrodes 14a and 14b, and a plurality of conductor layers 16.

The stacked body 12, as shown in FIG. 2, has a structure in which a plurality of insulator layers 13 are stacked in the up-down direction. The stacked body 12 has a rectangular parallelepiped shape. The stacked body 12, as shown in FIG. 1, has an upper surface SU, a mounting surface SD, a left surface SL, a right surface SR, a front surface SF, and a back surface SB. The upper surface SU is oriented in the up direction. The mounting surface SD is oriented in the down direction. The left surface SL, the right surface SR, the front surface SF, and the back surface SB are side surfaces located between the mounting surface SD and the upper surface SU.

In addition, each edge of the stacked body 12 is rounded. Therefore, the stacked body 12 has a first curved surface S1 (see FIG. 2) located between the mounting surface SD and the right surface (the side surface) SR, and a second curved surface S2 (see FIG. 3) located between the upper surface SU and the right surface (the side surface) SR. Hereinafter, as shown in FIG. 2, a region with the first curved surface S1 in the up-down direction is defined as a first region A1. As shown in FIG. 3, a region with the second curved surface S2 in the up-down direction is defined as a second region A2. As shown in FIG. 2 and FIG. 3, a region without the first curved surface S1 or the second curved surface S2 in the up-down direction is defined as a third region A3. The third region A3 is located between the first region A1 and the second region A2.

The plurality of conductor layers 16, as shown in FIG. 2 and FIG. 3, are provided in the stacked body 12. The plurality of conductor layers 16 are stacked in the up-down direction, together with a plurality of insulator layers 13. The plurality of conductor layers 16 include conductor layers 16a to 16c located in the first region A1, and conductor layers 16d to 16f located in the second region A2. The conductor layers 16a to 16c are arranged in this order from the top to the bottom. The conductor layers 16d to 16f are arranged in this order from the bottom to the top.

The mounting electrodes 14a and 14b are provided on the mounting surface SD, and are not provided on the left surface SL, the right surface SR, the front surface SF, the back surface SB (the side surfaces), the upper surface SU, the first curved surface S1, or the second curved surface S2. The mounting electrodes 14a and 14b are arranged in this order from the left to the right. The mounting electrodes 14a and 14b have a rectangular shape when viewed in the up-down direction.

Herein, as shown in FIG. 2 and FIG. 3, a cross-sectional surface parallel to the up-down direction and also including the mounting electrode 14a or the mounting electrode 14b is defined as a first cross-sectional surface. As shown in FIG. 2, in the first cross-sectional surface, a distance in the left-right direction (the orthogonal direction orthogonal to the up-down direction) between the plurality of conductor layers 16a to 16c located in the first region A1 among the plurality of conductor layers 16 and the right surface (the side surface) SR is longer than the shortest distance d0 in the left-right direction (the orthogonal direction orthogonal to the up-down direction) between the plurality of conductor layers 16 located in the third region A3 among the plurality of conductor layers 16 and the right surface (the side surface) SR.

Further, in the first cross-sectional surface, distances in the left-right direction (the orthogonal direction orthogonal to the up-down direction) between the plurality of conductor layers 16a to 16c located in the first region A1 among the plurality of conductor layers 16 and the right surface (the side surface) SR increases toward the mounting surface SD. In the present exemplary embodiment, the distances in the left-right direction between the plurality of conductor layers 16a to 16c and the right surface (the side surface) SR are respectively distances d1 to d3. In addition, the distance d1 is the shortest distance between the conductor layer 16a and the side surface in the insulator layer 13 in which the conductor layer 16a is provided. The distance d2 is the shortest distance between the conductor layer 16b and the side surface in the insulator layer 13 in which the conductor layer 16b is provided. The distance d3 is the shortest distance between the conductor layer 16c and the side surface in the insulator layer 13 in which the conductor layer 16c is provided. Then, d0<d1<d2<d3 holds.

In addition, as shown in FIG. 3, in the first cross-sectional surface, a distance in the left-right direction (the orthogonal direction orthogonal to the up-down direction) between the plurality of conductor layers 16d to 16f located in the second region A2 among the plurality of conductor layers 16 and the right surface (the side surface) SR is longer than the shortest distance d0 in the left-right direction (the orthogonal direction orthogonal to the up-down direction) between the plurality of conductor layers 16 located in the third region A3 among the plurality of conductor layers 16 and the right surface (the side surface) SR.

Further, as shown in FIG. 3, in the first cross-sectional surface, distances d4 to d6 in the left-right direction (the orthogonal direction orthogonal to the up-down direction) between the plurality of conductor layers 16d to 16f located in the second region A2 among the plurality of conductor layers 16 and the right surface (the side surface) SR increase toward the upper surface SU. In the present exemplary embodiment, the distances in the left-right direction between the plurality of conductor layers 16d to 16f and the right surface (the side surface) SR are respectively the distances d4 to d6. In addition, the distance d4 is the shortest distance between the conductor layer 16d and the side surface in the insulator layer 13 in which the conductor layer 16d is provided. The distance d5 is the shortest distance between the conductor layer 16e and the side surface in the insulator layer 13 in which the conductor layer 16e is provided. The distance d6 is the shortest distance between the conductor layer 16f and the side surface in the insulator layer 13 in which the conductor layer 16f is provided. Then, d0<d4<d5<d6 holds.

The electronic component 10 as described above, as shown in FIG. 2, is mounted on the circuit board 110. The circuit board 110 includes a board body 112, a ground conductor layer 116, and mounting electrodes 114a and 114b. The mounting electrode 114a is not illustrated. The board body 112 has a plate shape having an upper principal surface and a lower principal surface. The ground conductor layer 116 is provided in the board body 112. The mounting electrodes 114a and 114b are provided on the upper principal surface of the board body 112.

The electronic component 10 is mounted on the circuit board 110 with solder 200a and 200b. The solder 200a is not illustrated. Specifically, the mounting electrode 14a is fixed to the mounting electrode 114a with the solder 200a. The mounting electrode 14b is fixed to the mounting electrode 114b with the solder 200b.

### Effects

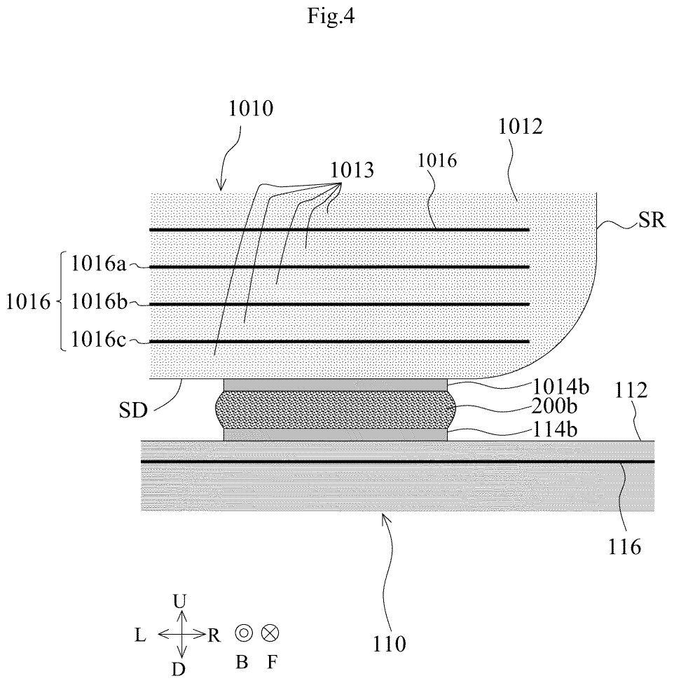

According to the electronic component 10, stray capacitance to be generated between the conductor layers 16 in the stacked body 12 and the conductor layer of the circuit board 110 is able to be reduced. FIG. 4 is a cross-sectional view of an electronic component 1010 according to a comparative example.

The electronic component 1010 is different in d1=d2=d3 from the electronic component 10. In the electronic component 1010, the stray capacitance is generated between conductor layers 1016a to 1016c and the ground conductor layer 116. Such stray capacitance becomes a cause to vary the electrical characteristics of the electronic component 1010 from desired electrical characteristics.

Therefore, in the electronic component 10, in the first cross-sectional surface, a distance in the left-right direction (the orthogonal direction orthogonal to the up-down direction) between the plurality of conductor layers 16a to 16c located in the first region A1 among the plurality of conductor layers 16 and the right surface (the side surface) SR is longer than the shortest distance d0 in the left-right direction (the orthogonal direction orthogonal to the up-down direction) between the plurality of conductor layers 16 located in the third region A3 among the plurality of conductor layers 16 and the right surface (the side surface) SR. Accordingly, the right end of the conductor layer 16c is located closer to the left than the right end of the conductor layer 1016c. As a result, when viewed in the up-down direction, an area in which the conductor layer 16c overlaps with the ground conductor layer 116 is smaller than an area in which the conductor layer 1016c overlaps with the ground conductor layer 116. Accordingly, the stray capacitance to be generated at the conductor layer 16c is smaller than the stray capacitance to be generated at the conductor layer 1016c.

Further, in the electronic component 10, the stacked body 12 has the first curved surface S1 located between the mounting surface SD and the right surface (the side surface) SR. Accordingly, a volume of the stacked body 12 between the conductor layers 16a and 16b and the ground conductor layer 116 decreases, and a volume of air between the conductor layers 16a and 16b and the ground conductor layer 116 increases. The dielectric constant of the stacked body 12 is higher than the dielectric constant of air. As a result, the stray capacitance to be generated between the conductor layers 16a and 16b and the ground conductor layer 116 is reduced. It is to be noted that the stray capacitance to be generated between the conductor layers 16e and 16f and the metal member 300 is reduced for the same reason.

### First Exemplary Embodiment

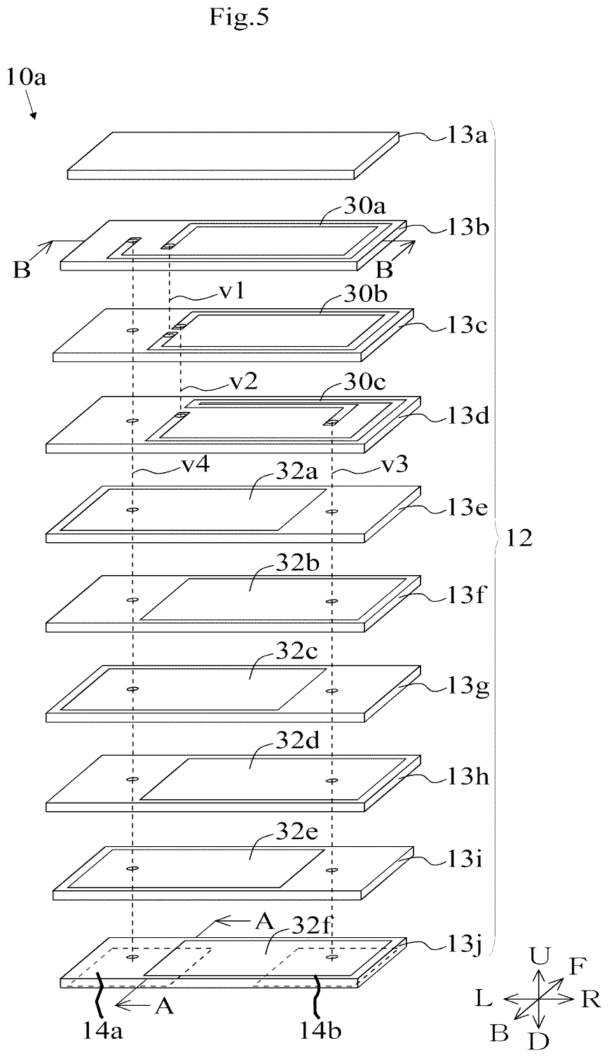

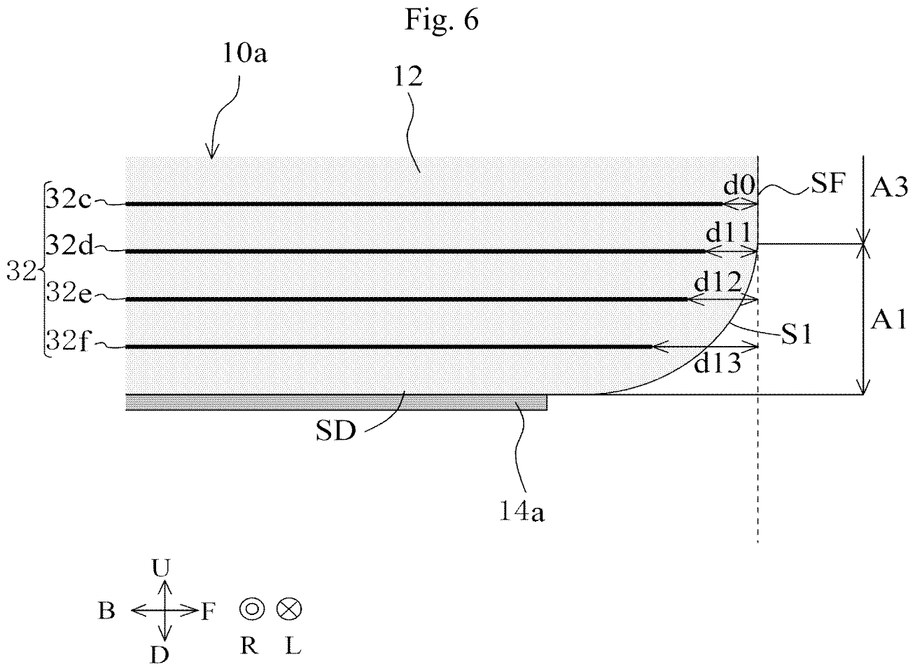

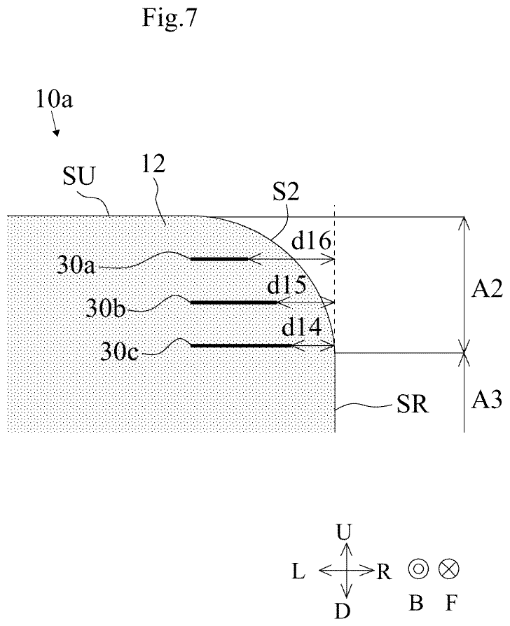

Hereinafter, an electronic component 10a according to a first exemplary embodiment of the present disclosure will be described with reference to drawings. FIG. 5 is an exploded perspective view of the electronic component 10a. FIG. 6 is a cross-sectional view taken along a line A-A of the electronic component 10a. FIG. 7 is a cross-sectional view taken along a line B-B of the electronic component 10a.

The electronic component 10a is an LC filter. The electronic component 10a includes a stacked body 12, mounting electrodes 14a and 14b, coil conductor layers (conductor layers) 30a to 30c, capacitor conductor layers (conductor layers) 32a to 32f, and interlayer connection conductors v1 to v4.

The stacked body 12 has a structure in which insulator layers 13a to 13j are stacked in the up-down direction. The insulator layers 13a to 13j are arranged in this order from the top to the bottom. It is to be noted that, since the structure of the stacked body 12 of the electronic component 10a is the same as the structure of the stacked body 12 of the electronic component 10, the description will be omitted. In addition, since the structure of the mounting electrodes 14a and 14b of the electronic component 10a is the same as the structure of the mounting electrodes 14a and 14b of the electronic component 10, the description will be omitted.

Each of the coil conductor layers 30a to 30c is provided on the upper principal surface of the insulator layers 13b to 13d. The coil conductor layers 30a to 30c have a partially cutout rectangular ring shape. Hereinafter, when viewed in the down direction, an end portion located upstream in the counterclockwise direction of the coil conductor layers 30a to 30c is called an upstream end portion. When viewed in the down direction, an end portion located downstream in the counterclockwise direction of the coil conductor layers 30a to 30c is called a downstream end portion.

The interlayer connection conductor v1 electrically connects the downstream end portion of the coil conductor layer 30a and the upstream end portion of the coil conductor layer 30b. The interlayer connection conductor v1 passes through the insulator layer 13b in the up-down direction. The interlayer connection conductor v2 electrically connects the downstream end portion of the coil conductor layer 30b and the upstream end portion of the coil conductor layer 30c. The interlayer connection conductor v2 passes through the insulator layer 13c in the up-down direction. The coil conductor layers (the plurality of conductor layers) 30a to 30c and the interlayer connection conductors v1 and v2 as described above are spiral coils having a coil axis extending in the up-down direction.

Each of the capacitor conductor layers 32a to 32f is provided on the upper principal surface of the insulator layers 13e to 13j. The capacitor conductor layer 32a is provided at a left portion and intermediate portion of the insulator layer 13e. The left portion is a portion located in the leftmost when the insulator layer is equally divided into three in the left-right direction. The intermediate portion is a portion located in the middle when the insulator layer is equally divided into three in the left-right direction. The right portion is a portion located in the rightmost when the insulator layer is equally divided into three in the left-right direction. Since the structure of the capacitor conductor layers 32c and 32e is the same as the structure of the capacitor conductor layer 32a, the description will be omitted. The capacitor conductor layer 32b is provided at a right portion and intermediate portion of the insulator layer 13f. Since the structure of the capacitor conductor layers 32d and 32f is the same as the structure of the capacitor conductor layer 32b, the description will be omitted. Accordingly, when viewed in the up-down direction, a portion of the capacitor conductor layers 32a, 32c, and 32e overlap with a portion of the capacitor conductor layers 32b, 32d, and 32f. Therefore, the capacitance is provided between the capacitor conductor layers 32a, 32c, and 32e and the capacitor conductor layers 32b, 32d, and 32f. The capacitor conductor layers (the plurality of conductor layers) 32a to 32f as described above are capacitors.

The interlayer connection conductor v3 electrically connects the downstream end portion of the coil conductor layer 30c, the capacitor conductor layers 32b, 32d, and 32f, and the mounting electrode 14b. The interlayer connection conductor v3 passes through the insulator layers 13d to 13j in the up-down direction. The interlayer connection conductor v4 electrically connects the upstream end portion of the coil conductor layer 30a, the capacitor conductor layers 32a, 32c, and 32e, and the mounting electrode 14a. The interlayer connection conductor v4 passes through the insulator layers 13b to 13j in the up-down direction.

In the electronic component 10a as described above, an LC parallel resonant circuit in which a capacitor and a coil are connected in parallel is electrically connected between the mounting electrode 14a and the mounting electrode 14b.

In addition, as shown in FIG. 6, in the first cross-sectional surface, distances d11 to d13 in the front-back direction (the orthogonal direction orthogonal to the up-down direction) between the capacitor conductor layers (the plurality of conductor layers) 32d to 32f located in the first region A1 the coil conductor layers (the plurality of conductor layers) 30a to 30c and the capacitor conductor layers (the plurality of conductor layers) 32a to 32f and the front surface (the side surface) SF are longer than the shortest distance d0 in the front-back direction (the orthogonal direction orthogonal to the up-down direction) between the capacitor conductor layers (the plurality of conductor layers) 32a to 32c located in the third region A3 among the coil conductor layers (the plurality of conductor layers) 30a to 30c and the capacitor conductor layers (the plurality of conductor layers) 32a to 32f and the front surface (the side surface) SF.

Further, in the first cross-sectional surface, distances d11 to d13 in the front-back direction (the orthogonal direction orthogonal to the up-down direction) between the capacitor conductor layers (the plurality of conductor layers) 32d to 32f located in the first region A1 among the coil conductor layers (the plurality of conductor layers) 30a to 30c and the capacitor conductor layers (the plurality of conductor layers) 32a to 32f and the front surface (the side surface) SF increase toward the mounting surface SD. In the present exemplary embodiment, the distances in the front-back direction between the capacitor conductor layers 32d to 32f and the front surface SF are respectively the distances d11 to d13. Then, d0<d11<d12<d13 holds.

In addition, as shown in FIG. 7, in the first cross-sectional surface, distances d14 to d16 in the left-right direction (the orthogonal direction orthogonal to the up-down direction) between the coil conductor layers (the plurality of conductor layers) 30a to 30c located in the second region A2 among the coil conductor layers (the plurality of conductor layers) 30a to 30c and the capacitor conductor layers (the plurality of conductor layers) 32a to 32f and the right surface (the side surface) SR are longer than the shortest distance d0 in the left-right direction (the orthogonal direction orthogonal to the up-down direction) between the capacitor conductor layers (the plurality of conductor layers) 32a to 32c located in the third region A3 among the coil conductor layers (the plurality of conductor layers) 30a to 30c and the capacitor conductor layers (the plurality of conductor layers) 32a to 32f and the right surface (the side surface) SR.

Further, as shown in FIG. 7, in the first cross-sectional surface, the distances d14 to d16 in the left-right direction (the orthogonal direction orthogonal to the up-down direction) between the coil conductor layers (the plurality of conductor layers) 30a to 30c located in the second region A2 among the coil conductor layers (the plurality of conductor layers) 30a to 30c and the capacitor conductor layers (the plurality of conductor layers) 32a to 32f and the right surface (the side surface) SR increase toward the upper surface SU. In the present exemplary embodiment, the distances in the left-right direction between the coil conductor layers (the plurality of conductor layers) 30a to 30c and the right surface (the side surface) SR are respectively the distances d14 to d16. Then, d0<d14<d15<d16 holds.

The electronic component 10a as described above has the same advantageous effects as the electronic component 10.

### Second Exemplary Embodiment

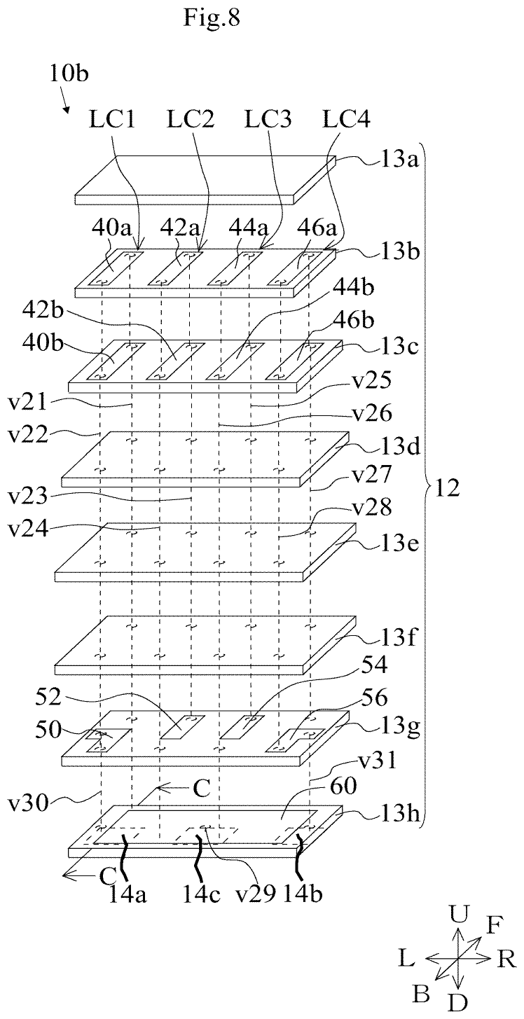

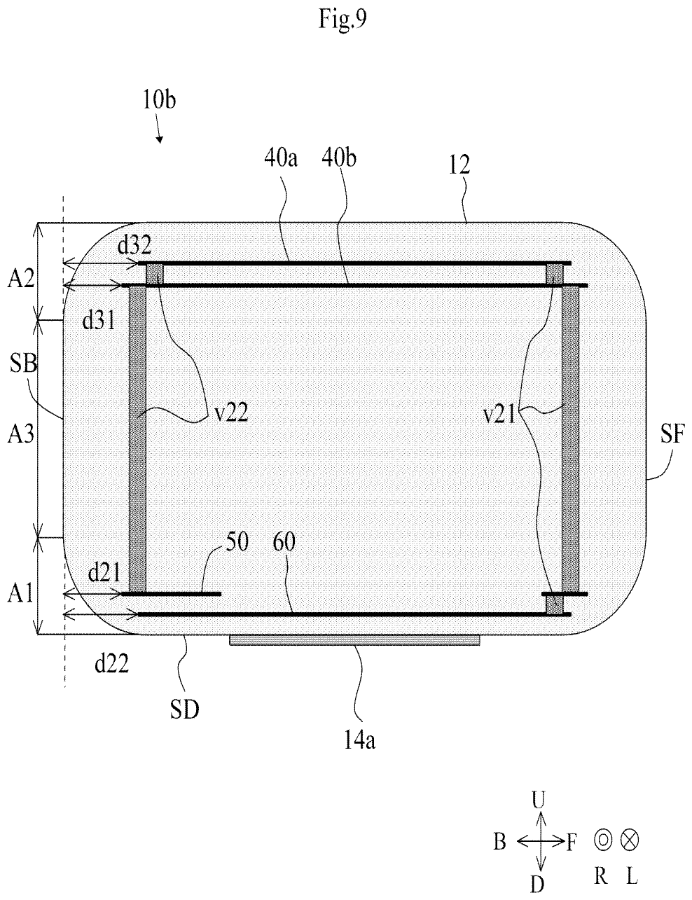

Hereinafter, an electronic component 10b according to a second exemplary embodiment of the present disclosure will be described with reference to drawings. FIG. 8 is an exploded perspective view of the electronic component 10b. FIG. 9 is a cross-sectional view taken along a line C-C of the electronic component 10b.

The electronic component 10b is an LC filter. The electronic component 10b includes a stacked body 12, mounting electrodes 14a, 14b, and 14c, loop conductor layers (conductor layers) 40a, 40b, 42a, 42b, 44a, 44b, 46a, and 46b, capacitor conductor layers (conductor layers) 50, 52, 54, 56, and 60, and interlayer connection conductors v21 to v31.

The stacked body 12 has a structure in which insulator layers 13a to 13h are stacked in the up-down direction. The insulator layers 13a to 13h are arranged in this order from the top to the bottom. It is to be noted that, since the structure of the stacked body 12 of the electronic component 10b is the same as the structure of the stacked body 12 of the electronic component 10, the description will be omitted. In addition, since the structure of the mounting electrodes 14a and 14b of the electronic component 10b is the same as the structure of the mounting electrodes 14a and 14b of the electronic component 10, the description will be omitted. Moreover, the mounting electrode 14c is provided on the lower principal surface of the insulator layer 13h. The mounting electrode 14c is located between the mounting electrode 14a and the mounting electrode 14b in the left-right direction.

The capacitor conductor layer 50 is provided on the upper principal surface of the insulator layer 13g. The capacitor conductor layer 60 is provided on the upper principal surface of the insulator layer 13h. The capacitor conductor layer 50 overlaps with the capacitor conductor layer 60, when viewed in the up-down direction. Accordingly, the capacitance is generated between the capacitor conductor layer 50 and the capacitor conductor layer 60. Therefore, the capacitor conductor layers (the plurality of conductor layers) 50 and 60 are capacitors.

Each of the loop conductor layers 40a and 40b is provided on the upper principal surface of the insulator layers 13b and 13c. Each of the loop conductor layers 40a and 40b is located near the left side of the insulator layers 13b and 13c. The loop conductor layers 40a and 40b extend in the front-back direction. The loop conductor layer 40a overlaps with the loop conductor layer 40b, when viewed in the up-down direction.

The interlayer connection conductor v21 electrically connects a front end portion of the loop conductor layer 40a, a front end portion of the loop conductor layer 40b, and the capacitor conductor layer 60. The interlayer connection conductor v21 passes through the insulator layers 13b to 13g in the up-down direction. The interlayer connection conductor v22 electrically connects a back end portion of the loop conductor layer 40a, a back end portion of the loop conductor layer 40b, and the capacitor conductor layer 50. The interlayer connection conductor v22 passes through the insulator layers 13b to 13f in the up-down direction. The loop conductor layers (the plurality of conductor layers) 40a and 40b and the interlayer connection conductors v21 and v22 are loop coils. In addition, the loop conductor layers 40a and 40b, the interlayer connection conductors v21 and v22, and the capacitor conductor layers 50 and 60 define an LC parallel resonator LC1.

The interlayer connection conductor v30 electrically connects the capacitor conductor layer 50 and the mounting electrode 14a. The interlayer connection conductor v30 passes through the insulator layers 13g and 13h in the up-down direction. Accordingly, the LC parallel resonator LC1 is connected to the mounting electrode 14a.

The capacitor conductor layer 52 is provided on the upper principal surface of the insulator layer 13g. The capacitor conductor layer 60 is provided on the upper principal surface of the insulator layer 13h. The capacitor conductor layer 52 overlaps with the capacitor conductor layer 60, when viewed in the up-down direction. Accordingly, the capacitance is generated between the capacitor conductor layer 52 and the capacitor conductor layer 60. Therefore, the capacitor conductor layers 52 and 60 are capacitors.

Each of the loop conductor layers 42a and 42b is provided on the upper principal surface of the insulator layers 13b and 13c. Each of the loop conductor layers 42a and 42b is located on the right of the loop conductor layers 40a and 40b. The loop conductor layers 42a and 42b extend in the front-back direction. The loop conductor layer 42a overlaps with the loop conductor layer 42b, when viewed in the up-down direction.

The interlayer connection conductor v23 electrically connects a front end portion of the loop conductor layer 42a, a front end portion of the loop conductor layer 42b, and the capacitor conductor layer 52. The interlayer connection conductor v23 passes through the insulator layers 13b to 13f in the up-down direction. The interlayer connection conductor v24 electrically connects a back end portion of the loop conductor layer 42a, a back end portion of the loop conductor layer 42b, and the capacitor conductor layer 60. The interlayer connection conductor v24 passes through the insulator layers 13b to 13g in the up-down direction. The loop conductor layers 42a and 42b and the interlayer connection conductors v23 and v24 are loop coils. In addition, the loop conductor layers 42a and 42b, the interlayer connection conductors v23 and v24, and the capacitor conductor layers 52 and 60 define an LC parallel resonator LC2. The LC parallel resonator LC2 is electromagnetically coupled to the LC parallel resonator LC1.

The loop conductor layers 44a and 44b, the interlayer connection conductors v25 and v26, and the capacitor conductor layers 54 and 60 define an LC parallel resonator LC3. Since the loop conductor layers 44a and 44b, the interlayer connection conductors v25 and v26, and the capacitor conductor layer 54 have a symmetric structure to the loop conductor layers 42a and 42b, the interlayer connection conductors v23 and v24, and the capacitor conductor layer 52, the description will be omitted.

The loop conductor layers 46a and 46b, the interlayer connection conductors v27 and v28, and the capacitor conductor layers 56 and 60 define an LC parallel resonator LC4. Since the loop conductor layers 46a and 46b, the interlayer connection conductors v27, v28, and v31, and the capacitor conductor layer 56 have a symmetric structure to the loop conductor layers 40a and 40b, the interlayer connection conductors v21, v22, and v30, and the capacitor conductor layer 50, the description will be omitted.

The interlayer connection conductor v29 electrically connects the mounting electrode 14c and the capacitor conductor layer 60. The interlayer connection conductor v29 passes through the insulator layer 13h in the up-down direction. This interlayer connection conductor v29 is located in the first region A1.

In addition, as shown in FIG. 9, in the first cross-sectional surface, the distances in the front-back direction (the orthogonal direction orthogonal to the up-down direction) between the capacitor conductor layers (the plurality of conductor layers) 50 and 60 located in the first region A1 among the loop conductor layers (the plurality of conductor layers) 40a, 40b, 42a, 42b, 44a, 44b, 46a, and 46b and the capacitor conductor layers (the plurality of conductor layers) 50, 52, 54, 56, and 60 and the back surface (the side surface) SB increase toward the mounting surface SD. In the present exemplary embodiment, the distances in the front-back direction between the capacitor conductor layers 50 and 60 and the back surface SB are respectively distances d21 and d22. Then, d21<d22 holds. It is to be noted that the capacitor conductor layers 52, 54, 56, and 60 also have the same relationship as the capacitor conductor layers 50 and 60.

In addition, as shown in FIG. 9, in the first cross-sectional surface, the distances in the front-back direction (the orthogonal direction orthogonal to the up-down direction) between the loop conductor layers (the plurality of conductor layers) 40a and 40b located in the second region A2 among the loop conductor layers (the plurality of conductor layers) 40a, 40b, 42a, 42b, 44a, 44b, 46a, and 46b and the capacitor conductor layers (the plurality of conductor layers) 50, 52, 54, 56, and 60 and the back surface (the side surface) SB increase toward the upper surface SU. In the present exemplary embodiment, the distances in the front-back direction between the loop conductor layers (the plurality of conductor layers) 40a and 40b and the back surface (the side surface) SB are respectively distances d31 and d32. Then, d31<d32 holds. It is to be noted that the distances in the front-back direction (the orthogonal direction orthogonal to the up-down direction) between the loop conductor layers (the plurality of conductor layers) 40a and 40b located in the second region A2 among the loop conductor layers (the plurality of conductor layers) 40a, 40b, 42a, 42b, 44a, 44b, 46a, and 46b and the capacitor conductor layers (the plurality of conductor layers) 50, 52, 54, 56, and 60 and the front surface (the side surface) SF increase toward the upper surface SU. It is to be noted that the loop conductor layers 42a, 42b, 44a, 44b, 46a, and 46b also have the same relationship as the loop conductor layers 40a and 40b.

The electronic component 10b as described above has the same advantageous effects as the electronic component 10.

### Third Exemplary Embodiment

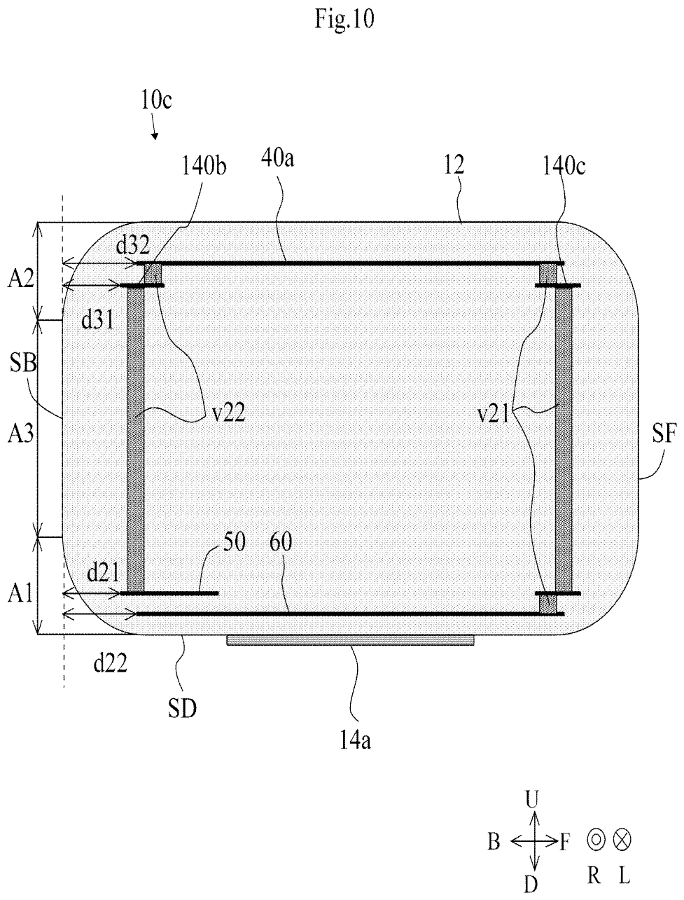

Hereinafter, an electronic component 10c according to a third exemplary embodiment of the present disclosure will be described with reference to drawings. FIG. 10 is a cross-sectional view taken along a line C-C of the electronic component 10c.

The electronic component 10c is different from the electronic component 10b in that loop conductor layers 140b and 140c instead of the loop conductor layer 40b are provided. The loop conductor layer 140b is equivalent to a left end portion of the loop conductor layer 40b. The loop conductor layer 140c is equivalent to a right end portion of the loop conductor layer 40b. Since the remaining structure of the electronic component 10c is the same as the structure of the electronic component 10b, the description will be omitted. The electronic component 10c has the same advantageous effects as the electronic component 10b.

### Other Exemplary Embodiments

Electronic components according to the present disclosure are not limited to the electronic components 10, and 10a to 10c, and various changes and modifications may be possible within the scope of the present disclosure. In addition, the structures of the electronic components 10, and 10a to 10c may be optionally combined.

It is to be noted that, in the electronic component 10, either one of the following (A) or (B) may hold.

(A) In the first cross-sectional surface, the distances in the left-right direction (the orthogonal direction orthogonal to the up-down direction) between the plurality of conductor layers 16a to 16c located in the first region A1 among the plurality of conductor layers 16 and the right surface (the side surface) SR increases toward the mounting surface SD.
(B) In the first cross-sectional surface, the distances d4 to d6 in the left-right direction (the orthogonal direction orthogonal to the up-down direction) between the plurality of conductor layers 16d to 16f located in the second region A2 among the plurality of conductor layers 16 and the right surface (the side surface) SR increase toward the upper surface SU.

It is to be noted that, in the electronic component 10a, either one of the following (C) or (D) may hold.

(C) In the first cross-sectional surface, the distances in the front-back direction (the orthogonal direction orthogonal to the up-down direction) between the capacitor conductor layers (the plurality of conductor layers) 32d to 32f located in the first region A1 among the coil conductor layers (the plurality of conductor layers) 30a to 30c and the capacitor conductor layers (the plurality of conductor layers) 32a to 32f and the front surface (the side surface) SF increase toward the mounting surface SD.

(D) In the first cross-sectional surface, the distances d14 to d16 in the left-right direction (the orthogonal direction orthogonal to the up-down direction) between the coil conductor layers (the plurality of conductor layers) 30a to 30c located in the second region A2 among the coil conductor layers (the plurality of conductor layers) 30a to 30c and the capacitor conductor layers (the plurality of conductor layers) 32a to 32f and the right surface (the side surface) SR increase toward the upper surface SU.

It is to be noted that, in the electronic components 10b and 10c, either one of the following (E) or (F) may hold.

(E) In the first cross-sectional surface, the distances in the front-back direction (the orthogonal direction orthogonal to the up-down direction) between the capacitor conductor layers (the plurality of conductor layers) 50 and 60 located in the first region A1 among the loop conductor layers (the plurality of conductor layers) 40a, 40b, 42a, 42b, 44a, 44b, 46a, and 46b and the capacitor conductor layers (the plurality of conductor layers) 50, 52, 54, 56, and 60 and the back surface (the side surface) SB increase toward the mounting surface SD.

(F) In the first cross-sectional surface, the distances in the front-back direction (the orthogonal direction orthogonal to the up-down direction) between the loop conductor layers (the plurality of conductor layers) 40a and 40b located in the second region A2 among the loop conductor layers (the plurality of conductor layers) 40a, 40b, 42a, 42b, 44a, 44b, 46a, and 46b and the capacitor conductor layers (the plurality of conductor layers) 50, 52, 54, 56, and 60 and the back surface (the side surface) SB increase toward the upper surface SU.

It is to be noted that the interlayer connection conductor may be located in the second region A2 and may pass through the insulator layer in the up-down direction.

It is to be noted that, in the first cross-sectional surface, the above describes that d1<d2<d3 holds. However, the distance d1 is the shortest distance between the conductor layer 16a and the side surface in the insulator layer 13 in which the conductor layer 16a is provided. The distance d2 is the shortest distance between the conductor layer 16b and the side surface in the insulator layer 13 in which the conductor layer 16b is provided. The distance d3 is the shortest distance between the conductor layer 16c and the side surface in the insulator layer 13 in which the conductor layer 16c is provided. Therefore, for example, the distance between the conductor layer 16a and the front surface SF may be the shortest distance, the distance between the conductor layer 16b and the right surface SR may be the shortest distance, and the distance between the conductor layer 16c and the back surface SB may be the shortest distance. In such a case, in the first cross-sectional surface, d1<d2<d3 may not need to hold. In such a case, in the entire stacked body 12, d1<d2<d3 may hold.

It is to be noted that, as long as d0<d1 holds, d1=d2=d3 may work.

The present disclosure includes the following structure.

(1) An electronic component including a stacked body including a structure in which a plurality of insulator layers are stacked in an up-down direction, a mounting surface oriented in a down direction, an upper surface oriented in an up direction, a side surface located between the mounting surface and the upper surface, a first curved surface located between the mounting surface and the side surface, and a second curved surface located between the upper surface and the side surface, a plurality of conductor layers provided in the stacked body, and a mounting electrode provided on the mounting surface and not provided on the side surface, the upper surface, the first curved surface, or the second curved surface, and a region with the first curved surface in the up-down direction is defined as a first region, a region with the second curved surface in the up-down direction is defined as a second region, a region without the first curved surface or the second curved surface in the up-down direction is defined as a third region, and at least one of a distance in an orthogonal direction orthogonal to the up-down direction between one or more conductor layers located in the first region among the plurality of conductor layers and the side surface, or a distance in the orthogonal direction orthogonal to the up-down direction between a plurality of conductor layers located in the second region among the plurality of conductor layers and the side surface is longer than a shortest distance in the orthogonal direction orthogonal to the up-down direction between a plurality of conductor layers located in the third region among the plurality of conductor layers and the side surface.

(2) An electronic component including a stacked body including a structure in which a plurality of insulator layers are stacked in an up-down direction, and a mounting surface oriented in a down direction, an upper surface oriented in an up direction, a side surface located between the mounting surface and the upper surface, a first curved surface located between the mounting surface and the side surface, and a second curved surface located between the upper surface and the side surface, a plurality of conductor layers provided in the stacked body, and a mounting electrode provided on the mounting surface and not provided on the side surface, the upper surface, the first curved surface, or the second curved surface, and a region with the first curved surface in the up-down direction is defined as a first region, a region with the second curved surface in the up-down direction is defined as a second region, and a distance in an orthogonal direction orthogonal to the up-down direction between a plurality of conductor layers located in the first region among the plurality of conductor layers and the side surface increases toward the mounting surface, and/or a distance in the orthogonal direction between a plurality of conductor layers located in the second region among the plurality of conductor layers and the side surface increases toward the upper surface.

(3) The electronic component according to (1) or (2) in which the plurality of conductor layers are coils.

(4) The electronic component according to (1) or (2) in which the plurality of conductor layers are capacitors.

(5) The electronic component according to any one of (1) to (4) further including an interlayer connection conductor located in the first region or the second region and passing through the plurality of insulator layers in the up-down direction.
10, 10a, 10b, 10c: electronic component
12: stacked body
13, 13a to 13j: insulator layer
14a to 14c: mounting electrode
16, 16a to 16f: conductor layer
30a to 30c: coil conductor layer
32a to 32f: capacitor conductor layer
40a, 40b, 42a, 42b, 44a, 44b, 46a, 46b, 140b, 140c: loop conductor layer
50, 52, 54, 56, 60: capacitor conductor layer
110: circuit board
112: board body
114a, 114b: mounting electrode
116: ground conductor layer
200a, 200b: solder
300: metal member
A1: first region
A2: second region
LC1 to LC4: LC parallel resonator
S1: first curved surface
S2: second curved surface
SB: back surface
SD: mounting surface
SF: front surface
SL: left surface
SR: right surface
SU: upper surface
v1 to v4, v21 to v30: interlayer connection conductor

1. An electronic component comprising:
a stacked body including:
a structure in which a plurality of insulator layers are stacked in an up-down direction;
a mounting surface oriented in a down direction;
an upper surface oriented in an up direction;
a side surface located between the mounting surface and the upper surface;
a first curved surface located between the mounting surface and the side surface; and
a second curved surface located between the upper surface and the side surface;
a plurality of conductor layers provided in the stacked body; and
a mounting electrode provided on the mounting surface and not provided on the side surface, the upper surface, the first curved surface, or the second curved surface, wherein:
a region with the first curved surface in the up-down direction is defined as a first region;
a region with the second curved surface in the up-down direction is defined as a second region;
a region without the first curved surface or the second curved surface in the up-down direction is defined as a third region; and
at least one of a distance in an orthogonal direction orthogonal to the up-down direction between one or more conductor layers located in the first region among the plurality of conductor layers and the side surface, or a distance in the orthogonal direction orthogonal to the up-down direction between one or more conductor layers located in the second region among the plurality of conductor layers and the side surface is longer than a shortest distance in the orthogonal direction orthogonal to the up-down direction between one or more conductor layers located in the third region among the plurality of conductor layers and the side surface.

2. An electronic component comprising:
a stacked body including:
a structure in which a plurality of insulator layers are stacked in an up-down direction;
a mounting surface oriented in a down direction;
an upper surface oriented in an up direction;
a side surface located between the mounting surface and the upper surface;
a first curved surface located between the mounting surface and the side surface; and
a second curved surface located between the upper surface and the side surface;
a plurality of conductor layers provided in the stacked body; and
a mounting electrode provided on the mounting surface and not provided on the side surface, the upper surface, the first curved surface, or the second curved surface, wherein:
a region with the first curved surface in the up-down direction is defined as a first region;
a region with the second curved surface in the up-down direction is defined as a second region; and
a distance in an orthogonal direction orthogonal to the up-down direction between one or more conductor layers located in the first region among the plurality of conductor layers and the side surface increases toward the mounting surface, and/or a distance in the orthogonal direction between one or more conductor layers located in the second region among the plurality of conductor layers and the side surface increases toward the upper surface.

3. The electronic component according to claim 1, wherein the plurality of conductor layers are coils.

4. The electronic component according to claim 1, wherein the plurality of conductor layers are capacitors.

5. The electronic component according to claim 1, further comprising an interlayer connection conductor located in the first region or the second region and passing through the plurality of insulator layers in the up-down direction.

6. The electronic component according to claim 2, wherein the plurality of conductor layers are coils.

7. The electronic component according to claim 2, wherein the plurality of conductor layers are capacitors.

8. The electronic component according to claim 2, further comprising an interlayer connection conductor located in the first region or the second region and passing through the plurality of insulator layers in the up-down direction.

9. The electronic component according to claim 3, further comprising an interlayer connection conductor located in the first region or the second region and passing through the plurality of insulator layers in the up-down direction.

10. The electronic component according to claim 4, further comprising an interlayer connection conductor located in the first region or the second region and passing through the plurality of insulator layers in the up-down direction.
